(19) United States
(12) Patent Application Publication
(10) Pub. No.: US 2025/0369899 A1
(43) Pub. Date: Dec. 4, 2025

(54) MASK METROLOGY MEASURING DEVICE AND METHOD FOR EXAMINING A PHOTOMASK

(71) Applicants: Carl Zeiss SMT GmbH, Oberkochen (DE); Carl Zeiss SMS Ltd., D.N. Misgav (IL)

(72) Inventors: Jan Reisloehner, Jena (DE); Thomas Frank, Jena (DE); Ulrich Matejka, Jena (DE); Lars-Christian Wittig, Jena (DE); Dirk Doering, Erfurt (DE); Ralph Semmler, Jena (DE); Thomas Thaler, Jena (DE); Vladimir Dmitriev, Tsurit (IL); Dominik Grau, Apolda (DE)

(21) Appl. No.: 19/304,769

(22) Filed: Aug. 20, 2025

Related U.S. Application Data
(63) Continuation of application No. PCT/EP2024/051030, filed on Jan. 17, 2024.

(30) Foreign Application Priority Data
Feb. 20, 2023 (DE) 102023104118.5

(51) Int. Cl. G01N 21/956; G01N 21/88

(52) U.S. Cl. CPC G01N 21/956; G01N 21/8806; G01N 2021/95676; G01N 2201/06113

(57) ABSTRACT

A mask metrology measuring device, comprising a radiation source, an illumination system, an imaging system and an image sensor. The illumination system is designed in a first measuring state to illuminate a first illumination field on a photomask with radiation emitted by the radiation source. The imaging system is designed to image an image representation on the image sensor from the first illumination field. The measuring device can be switched between a first measuring state and a second measuring state. A second illumination field on the photomask is illuminated in the second measuring state, with the first illumination field being arranged within the second illumination field. The first illumination field is not illuminated in the second measuring state. Stray light generated in the second measuring state is recorded by the image sensor.

### CROSS-REFERENCE TO RELATED APPLICATIONS

This application is a continuation of and claims benefit under 35 U.S.C. § 120 from PCT patent application PCT/EP2024/051030, filed on Jan. 17, 2024, which claims priority from German patent application 10 2023 104 118.5, filed on Feb. 20, 2023. The entire contents of each of these earlier applications are incorporated herein by reference.

### TECHNICAL FIELD

The invention relates to a mask metrology measuring device and a method for examining a photomask.

### BACKGROUND

Photomasks are used in microlithographic projection exposure apparatuses, which are used to produce integrated circuits with particularly small structures. The photomask (=reticle) illuminated by very short-wave deep ultraviolet or extreme ultraviolet radiation (DUV or EUV radiation) is imaged onto a lithographic object in order to transfer the mask structure to the lithographic object.

The dimensional accuracy of the structures on the photomask is crucial for a high quality of the image representation created on the lithographic object. In a usual procedure for producing a photomask, a check for determining whether a structure meets the specifications is performed once said structure of the photomask has been created. A correction is performed in regions of the photomask where this is not the case. A measuring device for checking the dimensional accuracy of a photomask is described in DE 10 2013 212 613 A1, for example.

For correction purposes, a laser beam can be applied to the substrate of the photomask in order to create local scattering centers, so-called pixels. The pixels, which correspond to a modification in the material structure of the photomask, may be created in selected regions of the photomask, which for example may extend over a few millimeters. Incident radiation is scattered off the pixels, and this reduces the intensity of radiation passing through the photomask in the region of the pixels. The local reduction in the intensity of the radiation contributes to an improvement in the quality of the image representation on the lithographic object.

Once the pixels have been written, a check is performed to determine whether the intended corrective effect has occurred. What is known as an aerial image of the photomask is created in a known method, within the scope of which the photomask is imaged not onto a lithographic object but onto an image sensor. The image representation on the image sensor can be used to assess whether the correction of the photomask was successful.

This check does not image the entire photomask onto the image sensor, but a local section of the photomask where the pixels have been added is illuminated and imaged.

The local illumination of a section of the photomask does not suffice for a complete ascertainment of the effects of the written pixels on the lithographic object. Should the photomask be illuminated over a larger area, pixels that are at a distance from the local section of the photomask might also have an effect on the relevant region of the image representation. This is because the radiation is scattered off the pixels in different directions, and a portion of the stray light may be incident on the relevant region of the image representation. This stray light component remains unconsidered if only a local section of the photomask is illuminated and imaged onto the image sensor.

An additional check is required to determine the effect that illuminating not only a local section but a larger region of the photomask has on the image representation. To date, this check was carried out by use of a wafer print by virtue of exposing a wafer in a microlithographic projection exposure apparatus. This type of check is time consuming and expensive.

### SUMMARY

The problem addressed by the invention is that of presenting a mask metrology measuring device and a method for examining a photomask, which avoid the disadvantages mentioned. The problem is solved by the features of the independent claims. Advantageous embodiments are specified in the dependent claims.

The mask metrology measuring device according to the invention comprises a radiation source, an illumination system, an imaging system and an image sensor. The illumination system is designed in a first measuring state to illuminate a first illumination field on a photomask with radiation emitted by the radiation source. The imaging system is designed to create an image representation on the image sensor from the first illumination field. The measuring device can be switched between the first measuring state and a second measuring state. A second illumination field on the photomask is illuminated in the second measuring state, with the first illumination field being arranged within the second illumination field and with the first illumination field not being illuminated. Stray light generated in the second measuring state is recorded by the image sensor.

The first measuring state corresponds to the conventional procedure in which a local section of the photomask is illuminated with the first illumination field in order to check the image representation of the first illumination field after the pixels have been introduced. The second measuring state is used to perform an examination of the surroundings of the first illumination field, while the first illumination field is not illuminated. Since there is no direct incidence of radiation on the image sensor on account of the masked first illumination field, the image sensor only measures the stray light component that is incident on the image sensor from the surroundings of the first illumination field. Since the pixels are not arranged in the same plane as the structure of the photomask examined in the first measuring state, the pixels are not imaged onto the image sensor. It is merely a matter of ascertaining the amount of stray light scattered off the pixels in the direction of the image sensor.

In the first measuring state, the measuring device may be configured such that it is not the entirety of the first illumination field but a section of the first illumination field that is imaged on the image sensor. The imaged section might be a central section of the first illumination field that is surrounded by the first illumination field all around. The section may extend over at least 40%, preferably at least 60%, of the edge length of the first illumination field. This may apply to both dimensions of the first illumination field. Stray light components arising in the edge regions of the first illumination field might also be incident on the image sensor.

Assuming that regions of the photomask located outside the second illumination field are so far away from the first illumination field that any stray light incident from there is no longer relevant, the sum of the radiation in the first measuring state and in the second measuring state is equal to the total radiation received by the image sensor when the photomask is illuminated over a large area. Suitable calculation steps allow the total radiation to be calculated from an image recorded in the first measuring state and an image recorded in the second measuring state.

In the second measuring state, an inverted stop may be arranged in the illumination beam path such that the inverted stop masks the first illumination field. This means that the inverted stop is arranged in the beam path of the illumination system in such a way that the radiation emitted by the radiation source is not incident on the first illumination field. The inverted stop should be removed from the illumination beam path in the first measuring state.

The first illumination field may correspond to a small partial section of the photomask. For example, if the photomask has a square shape and an edge length between 100 mm and 200 mm, then the edge length of the likewise square first illumination field may be between 5 μm and 100 μm, preferably between 10 μm and 50 μm. The area of the first illumination field may be smaller than the area of the photomask by at least a factor of 10⁵, preferably by at least a factor of 10⁷.

The second illumination field surrounds the first illumination field all around, with the area of the second illumination field being greater than the area of the first illumination field. For example, given a square shape, the second illumination field may have an edge length between 1 mm and 10 mm, preferably between 2 mm and 5 mm. The area of the second illumination field may be greater than the area of the first illumination field by at least a factor of 10³, preferably by at least a factor of 10⁴. The area of the second illumination field may be smaller than the area of the photomask by at least a factor of 10², preferably by at least a factor of 10³. In these specifications, the area of the first illumination field shall not be included in the area of the second illumination field.

In contrast to a measuring device used only to examine the first illumination field, the second measuring state places higher demands on the amount of radiation transmitted in the illumination system, since the radiation in the second illumination field is distributed over a larger area. In the second measuring state, the illumination system must provide a greater amount of radiation so that a clear signal is generated on the image sensor. Against this background, the invention proposes a plurality of measures to ensure that the second illumination field is exposed to a sufficient amount of radiation.

A pupil-forming mirror element or a mirror array may be arranged in a pupil plane of the illumination system. The mirror array may comprise a frame structure and a plurality of mirror elements movably mounted on the frame structure. Since the mirror elements are arranged in the pupil plane, the radiation reflected off each individual mirror element is distributed over the entire area of the illumination field in the plane of the photomask. The angle of incidence at which the radiation is incident on the illumination field differs from mirror element to mirror element. The angular distribution of the incident radiation is referred to as the illumination setting.

The illumination setting can be influenced by adjusting the mirror elements in the mirror array as desired. The procedure used to date is that individual mirror elements in the mirror array are set such that only some of the radiation incident on the mirror element is guided to the illumination field. The remaining radiation is lost and does not reach the image sensor.

In general, the illumination setting is predetermined by the photomask to be examined since the photomask should be examined with the same illumination setting that is also applied when the photomask is used in the microlithographic projection exposure apparatus. If the radiant power incident on the illumination field is divided by the number of mirror elements in the mirror array, then this yields an average contribution of the individual mirror element to the radiation in the illumination field. In an illumination setting, there are above-average mirror elements that make an above-average contribution and below-average mirror elements that make a below-average contribution.

The measuring device according to the invention may be configured such that the radiation incident on the mirror array has an intensity distribution that is adapted to the illumination setting. In other words, there is at least one above-average mirror element to which a radiant power that is greater than the average at the mirror elements is guided. In particular, a radiant power that is greater than the average at the mirror elements can be guided to at least 20%, preferably at least 50%, further preferably at least 70%, of the above-average mirror elements. There may be at least one below-average mirror element to which a radiant power that is lower than the average at the mirror elements is guided. In particular, a radiant power that is lower than the average at the mirror elements can be guided to at least 20%, preferably at least 50%, further preferably at least 70%, of the below-average mirror elements.

A first optical element may be arranged between the radiation source and the mirror array in the beam path of the illumination system; said optical element can be used to shape the beam path such that the latter has an intensity distribution that is adapted to the illumination setting. This may be an optical element through which the illumination beam path passes. According to an embodiment, the first optical element is a diffractive optical element (DOE). The DOE may comprise a glass substrate that is provided with an optical grating. The optical grating may be designed such that an output beam with an intensity distribution that is adapted to the illumination setting results from an input beam with a predetermined intensity distribution. Embodiments in which the first optical element is designed as a lens element or lens element arrangement are also possible.

In order to enable the use of the measuring device with different illumination settings, the illumination system may comprise an interchange device arranged between the radiation source and the mirror array such that the radiation incident on the mirror array in a first state of the interchange device has an intensity distribution that is adapted to a first illumination setting and that the radiation incident on the mirror array in a second state of the interchange device has an intensity distribution that is adapted to a second illumination setting. A first variant of the first optical element may be arranged in the illumination beam path in the first state of the interchange device, while this may be a second variant of the first optical element in the second state of the interchange device. The interchange device may be designed to introduce more than two variants of the first optical element into the illumination beam path, in particular at least three, preferably at least five variants. Each variant of the first optical element allows the intensity distribution of the radiation incident on the mirror array to be adapted to a different illumination setting.

The interchange device may be manipulated for the purpose of adjusting the intensity distribution, in order to switch the measuring device for use between a first type of photomask and a second type of photomask. It is also possible that the interchange device is manipulated when the measuring device is switched between the first measuring state and the second measuring state.

In previous measuring devices for examining microlithographic photomasks, the illumination system is usually designed such that the beam path is incident multiple times on a mirror array with a plurality of mirror elements. The invention proposes an alternative configuration of the illumination system, in which the beam path is reflected off such a mirror array exactly once. This makes a contribution to reducing the radiation losses in the illumination system.

Optical components arranged in the illumination beam path may be modified mechanically in order to switch the measuring device between the first measuring state and the second measuring state. In particular, optical components may be introduced into the beam path or removed from the beam path. The measuring device may comprise one or more actuators for moving the components. Provision may be made for a control unit that transmits control signals in order to control the actuators. The control unit may be designed to switch the measuring device between the first measuring state and the second measuring state.

In the first measuring state, a first field stop may be arranged in the illumination beam path such that the radiation is incident on the first illumination field, and regions of the photomask located outside the first illumination field are not illuminated. In the second measuring state, the first field stop may be removed from the illumination beam path.

In the first measuring state, a diffractive optical element in the form of a first field DOE for field generation may be arranged in a pupil plane of the illumination system arranged between the mirror array and the condenser optics unit.

In the second measuring state, a second field stop may be arranged in the illumination beam path such that the radiation is not incident on the region of the photomask located outside the second illumination field. In the first measuring state, the second field stop may be removed from the illumination beam path. The inverted stop used to mask the first illumination field may be arranged in the same plane of the illumination beam path as the second field stop. In an embodiment, the inverted stop is a constituent part of the second field stop.

In the second measuring state, a diffractive optical element in the form of a second field DOE may be arranged in a pupil plane of the illumination system arranged between the mirror array and the condenser optics unit. The second field DOE may be arranged in the same pupil plane as the first field DOE or in a different pupil plane to the first field DOE. In the first measuring state, the second field DOE may be removed from the illumination beam path.

The state of the imaging system, the state of a condenser optics unit of the illumination system and/or the position of the image sensor may be identical in both the first measuring state and the second measuring state. As a consequence, a significant portion of the radiation guided to the second illumination field is not incident on the image sensor, since the first illumination field imaged on the image sensor is masked at the time. In the second measuring state, therefore, only the radiation scattered in the direction of the image sensor off pixels located outside the first illumination field is incident on the image sensor.

The invention encompasses the idea that those optical components that are required in the first measuring state for achieving a sufficient image quality and are arranged in the beam path of the illumination system in the first measuring state are removed from the beam path of the illumination system in the second measuring state. This may comprise a polarization filter, a polarization controller and/or a beam attenuator. An adjustable beam attenuator, which in the first measuring state attenuates the radiation emitted by the radiation source and in the second measuring state is switched to pass, is also possible.

A further contribution to reducing the radiation losses in the illumination system can be made by a prism arrangement that has the features set forth below. The prism arrangement may preferably comprise two prisms which are arranged between the radiation source and the first optical element that is used to adapt the intensity distribution to the illumination setting. The prism arrangement may be set such that the illumination beam path is deflected through 90°. Each of the preferably two prisms may have a prism angle of between 55° and 65°. In this context, it may be advantageous to choose the prism angles of the preferably two prisms to be identical. In addition, the angle of incidence of the radiation can be the same for each of the prisms. The adjustment of the prism arrangement can be simplified if the exit face of the first prism is aligned perpendicular to the beam path entering the first prism. Such a prism arrangement may contribute to extending an incident beam laterally in one dimension. This may be helpful should the incident beam have a larger extent in one dimension than in the other dimension when viewed in cross section. Furthermore, by virtue of the direction of propagation of the radiation being wavelength dependent after passing through the prism arrangement, such a prism arrangement may contribute to increasing the divergence of the incident radiation in one dimension should said radiation contain multiple wavelengths. This may be advantageous should the incident beam have a larger divergence in one dimension than in the other dimension.

A further option for obtaining sufficient signal strength on the image sensor consists in adapting the exposure time of the image sensor. A control unit of the measuring device may be configured such that the exposure time is longer in the second measuring state than in the first measuring state. In particular, the exposure time in the second measuring state may be longer than the exposure time in the first measuring state at least by a factor of 2, further preferably at least by a factor of 5. For example, the exposure time in the first measuring state may be between 0.1 s and 0.5 s.

It is further advantageous if the number of mirror surfaces at which the radiation is reflected within the illumination system is small. The invention proposes to design the illumination beam path such that the radiation is reflected off no more than five mirror surfaces, preferably off no more than four mirror surfaces.

A beam splitter used to guide a portion of the radiation to an energy monitor may be arranged in the illumination beam path. The measured values from the energy monitor may serve as a reference for the total amount of radiation guided to the illumination field. The image data recorded by the image sensor may be normalized in terms of an energy on the basis of the measured values from the energy monitor. The beam splitter may be arranged between the mirror array and a condenser optics unit of the illumination beam path.

The measuring device according to the invention may comprise an XY-positioner that carries the photomask. The XY-positioner can be used to move the photomask perpendicular to the direction of the illumination beam path in order to position the photomask such that the illumination beam path is incident on a different region of the photomask. This opens up the possibility of examining different regions of the photomask.

The radiation source may be a laser radiation source. The emitted illumination radiation preferably has the same wavelength that is also applied in the microlithographic projection exposure apparatus in which the photomask is used. This may be DUV radiation in the deep ultraviolet spectral range with a wavelength between 100 nm and 300 nm. The wavelength is 193 nm in an embodiment.

In an alternative embodiment of the invention, the second illumination field is not subjected to a uniform exposure process but scanned with a laser beam in the second measuring state. For this purpose, the illumination system can be configured such that a laser beam with a small beam diameter is guided to a scan optics unit and the scan optics unit is controlled such that the laser beam scans the second illumination field in a temporal sequence. The scan optics unit may be controlled in such a way that the first illumination field is excluded from the scanning process. In this way, the scanning can be restricted to the second illumination field without a stop that masks the first illumination field being arranged in the beam path of the illumination system. The scan optics unit may comprise two scanning mirrors, wherein each scanning mirror can swivel about an axis. The axes may be orthogonal to each other. A single scanning mirror that can be swivelled about two axes is also possible. Alternatively, a design in which the scan optics unit comprises a scanning mirror and a rotating wedge is also possible.

The invention also relates to a method for examining a photomask, wherein a first illumination field on a photomask is illuminated in a first measurement run with radiation emitted by a radiation source and wherein an image representation is created on the image sensor from the first illumination field. A second illumination field on the photomask is illuminated in a second measurement run, with the first illumination field being arranged within the second illumination field and with the first illumination field not being illuminated in the second measurement state. Stray light generated in the second measuring state is recorded by the image sensor.

The disclosure encompasses developments of the method with features which are described in the context of the measuring device according to the invention. The disclosure encompasses developments of the measuring device with features that are described in the context of the method according to the invention.

### BRIEF DESCRIPTION OF DRAWINGS

The invention will be described by way of example below on the basis of advantageous embodiments by reference to the accompanying drawings. In the figures:

FIG. 1: shows a schematic illustration of a measuring device according to the invention;

FIG. 2: shows a view from above of a photomask with a second illumination field;

FIG. 3: shows an enlarged illustration of the second illumination field from FIG. 2;

FIG. 4: shows a schematic illustration of beam paths in a photomask;

FIG. 5: shows a schematic illustration of the first measuring state;

FIG. 6: shows a schematic illustration of the second measuring state;

FIG. 7: shows the illumination system of a measuring device according to the invention in the first measuring state;

FIG. 8: shows the illumination system of a measuring device according to the invention in the second measuring state;

FIG. 9: shows a schematic illustration of a 4f optics unit;

FIG. 10: shows the prism arrangement of the illumination system from FIGS. 8 and 9;

FIG. 11: shows a detail of an alternative embodiment of a measuring device according to the invention;

FIG. 12: shows an exemplary intensity distribution in an illumination beam path that is adapted to the illumination setting.

### DETAILED DESCRIPTION

A mask metrology measuring device according to the invention is used to examine the structure of a photomask 17. The photomask 17 is intended to be used in a microlithographic projection exposure apparatus (not illustrated). In the microlithographic projection exposure apparatus, the photomask 17 is illuminated with deep-ultraviolet radiation (DUV radiation) having a wavelength of, for example, 193 nm in order to image a structure formed on the photomask 17 onto the surface of a lithographic object in the form of a wafer. The wafer is coated with a photoresist that reacts to the DUV radiation. The measuring device is used to examine whether the structure on the photomask 17 corresponds to the dimensional specifications.

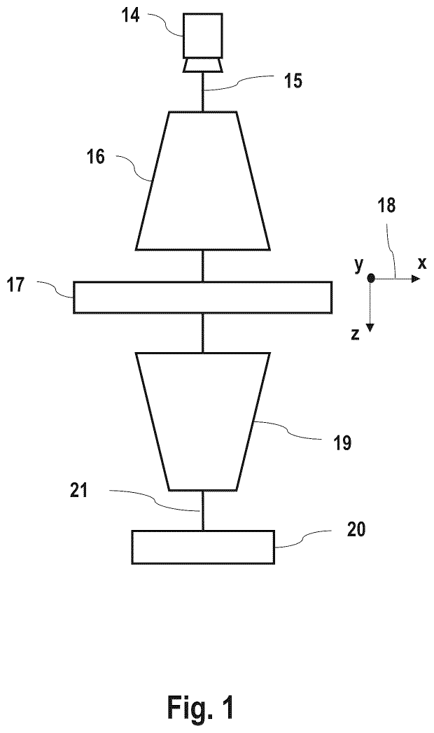

According to FIG. 1, the photomask 17 is arranged in the measuring device in such a way that a beam path emanating from a laser radiation source 14 passes through the photomask 17 and is guided to an image sensor 20. The radiation has a wavelength of 193 nm, which corresponds to the DUV radiation used in the microlithographic projection exposure apparatus. Arranged between the laser radiation source 14 and the photomask 17 is an illumination system 16 with which the laser beam emitted by the laser radiation source 14 is shaped such that it uniformly illuminates an illumination field within the area of the photomask 17. The structure of the photomask 17 is imaged onto an image sensor 20 using an imaging system 19. The portion of the beam path between the laser light source 14 and the photomask 17 is referred to as the illumination beam path 15. The portion of the beam path between the photomask 17 and the image sensor 20 is referred to as the imaging beam path 21.

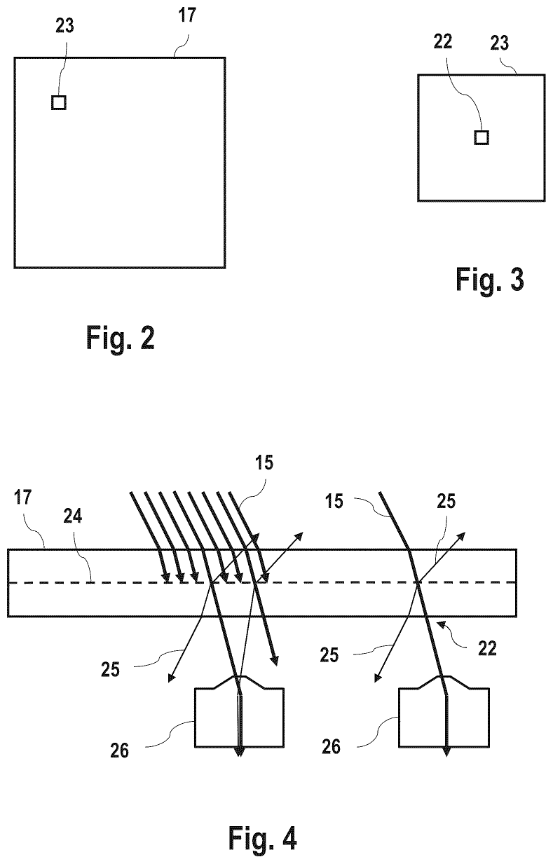

According to FIG. 2, the illumination field illuminated by the illumination system 16 is small in comparison with the surface of the photomask 17. FIG. 2 shows the second illumination field 23 in an illustration that is not true to scale; according to FIG. 3, the first illumination field 22 is significantly smaller yet again. In an exemplary embodiment, the photomask 17 is square with an edge length of approximately 150 mm. The second illumination field may also be square and have an edge length of 4 mm, for example. The likewise square first illumination field 22 may have an edge length of 30 μm, for example.

In the measuring device, the photomask 17 is arranged on an XY-positioner 18, which is indicated schematically in FIG. 1. The illumination beam path 15 can be directed at different regions of the photomask 17 by moving the photomask 17 in the XY-plane.

Conventional measuring devices are configured to generate a high-resolution image representation of the first (small) illumination field 22 on the image sensor. The right-hand part of the illustration in FIG. 4 shows the case where the illumination beam path 15 is incident on the first illumination field 22 only. Some of the radiation is scattered off pixels 24 created in the substrate of the photomask 17. The stray light components 25 are not incident on the lens 26 of the imaging system 19, and so the stray light components 25 do not contribute to the signal measured with the image sensor 20.

This is unlike what is shown in the left-hand part of the illustration in FIG. 4, where the illumination beam path 15 illuminates a larger region of the photomask 17. It is still the case that the only portion of the illumination beam path 15 that enters directly into the lens 26 of the imaging system 19 is the portion incident on the first (small) illumination field 22. However, stray light components 25 generated in regions of the photomask 17 outside the first illumination field 22 enter into the lens 16 of the imaging system 19 and hence contribute to the signal measured by the image sensor 20.

The invention proposes to equip the measuring device with a first measuring state in which the illumination beam path 15 illuminates only the first illumination field 22 such that an image representation of the photomask structure in the region of the first illumination field 22 is created on the image sensor 20. In a second measuring state, the illumination beam path 15 is directed at the second (large) illumination field 23, while the first illumination field 22 is masked. In the second measuring state, only the stray light components 25 enter the lens 26 of the imaging system 19 and are recorded by the image sensor 20. Suitable calculation steps allow an overall image to be calculated from an image representation recorded in the first measuring state and the stray light recorded in the second measuring state. This overall image corresponds to the radiation that is incident on the relevant section of the wafer in the microlithographic projection exposure apparatus.

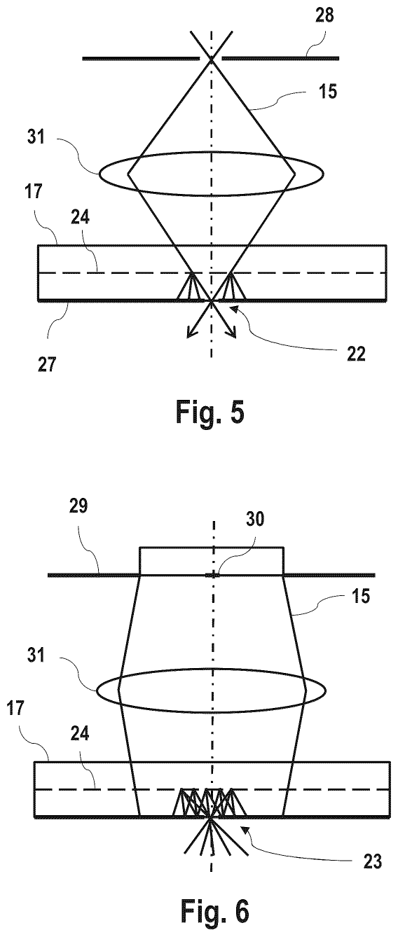

FIG. 5 schematically illustrates a section of the illumination beam path 15 in the first measuring state. A first field stop 28 is arranged in the illumination beam path 15 such that, in combination with a condenser optics unit 31, the first illumination field 22 is illuminated with uniform intensity. The first illumination field 22 is arranged on the underside of the photomask 17, where the structure of the photomask 17 is applied in the form of a chromium coating. The substrate of the photomask 17 is made of glass.

According to FIG. 6, a second field stop 29 rather than the first field stop 28 is arranged in the illumination beam path 15 in the second measuring state. The second field stop 29 comprises an inverted stop 30 that is used to mask the first illumination field 22. In other words, the inverted stop 30 has the effect of preventing the illumination radiation 15 from being incident on the first illumination field 22. The outer edge of the inverted stop 30 defines the inner edge of the second illumination field 23. The inner edge of the second field stop 29 corresponds to the outer edge of the second illumination field 23. The second illumination field 23 is illuminated uniformly by way of the condenser optics unit 31.

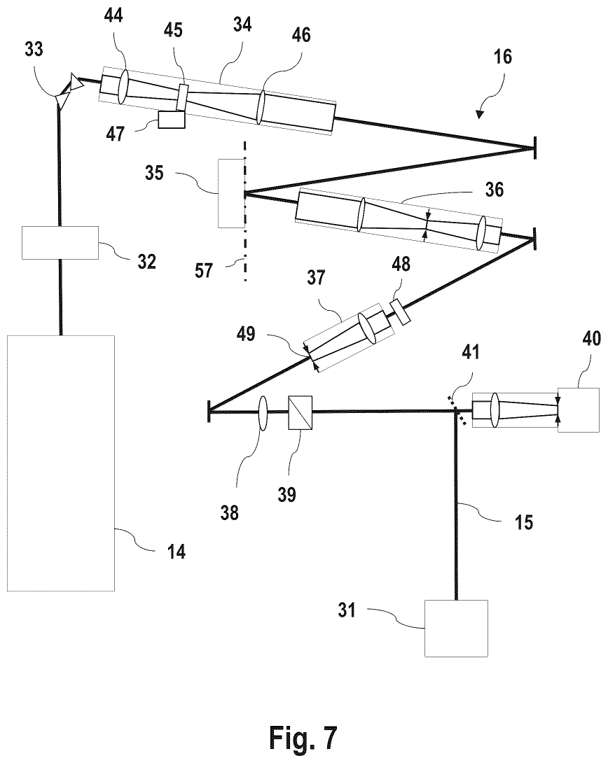

For the first measuring state of the measuring device, FIG. 7 schematically shows the illumination beam path 15 between the laser radiation source 14 and the condenser optics unit 31. A laser beam emitted by the laser radiation source 14 is initially guided through a beam attenuator 32. The beam attenuator 32 is set such that the intensity of the laser beam is matched to the sensitivity of the image sensor 20. A prism arrangement 33, which is shown in enlarged fashion in FIG. 10, is used to deflect the illumination beam path 15 through 90° and simultaneously expand the beam cross section laterally. The prism arrangement 33 comprises two prisms 42, 43, which have the same prism angles and which are arranged such that the angle of incidence is the same for both prisms 42, 43. The exit face of the first prism 42 is aligned perpendicular to the direction of the incident beam, thereby facilitating the adjustment of the prism arrangement 33.

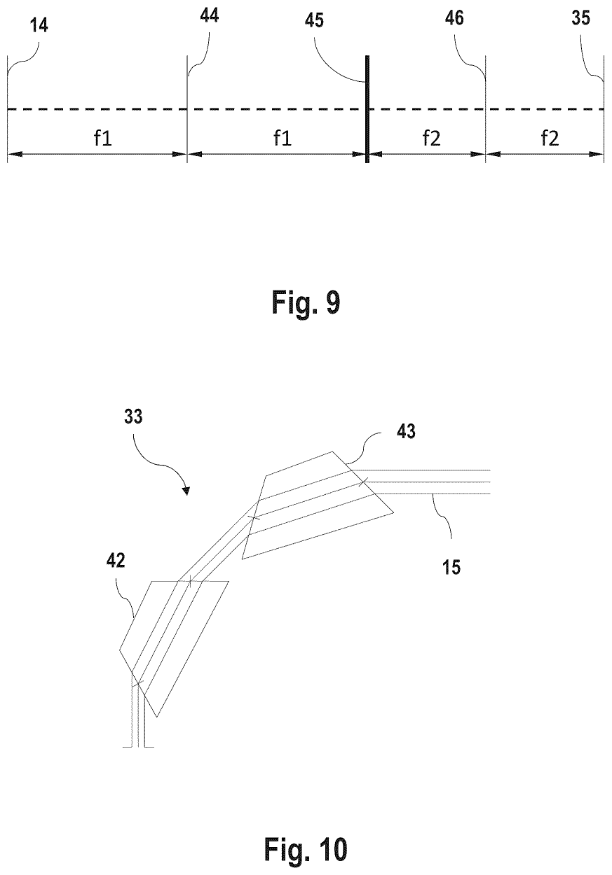

Following the prism arrangement 33, the illumination beam path 15 is incident on a first optics assembly 34. The optics assembly 34 comprises a 4f optics unit with a first lens element 44 and a second lens element 46. The first lens element 44 is arranged at a distance f1 from the output of the laser light source 14, and this distance corresponds to the focal length of the first lens element 44; see FIG. 9. A first DOE 45 is arranged at the same distance f1 on the other side of the first lens element 44 and used to adapt the intensity distribution in the cross section of the illumination beam path 15 to the illumination setting. The first DOE 45 corresponds to a first optical element within the meaning of the invention.

FIG. 12 plots the cross section of the illumination beam path 15 on the horizontal axis and the intensity of the radiation on the vertical axis. In this example, the illumination beam path 15 has an annular intensity distribution 58 with a low intensity in the center of the illumination beam path 15 and a high intensity extending around the center in annular fashion.

Other illumination settings require different intensity distributions in the cross section of the illumination beam path 15. The first DOE 45 is therefore supported by an interchange device 47 that is designed to position different DOE at this point in the illumination beam path 15, depending on the desired illumination setting.

According to FIG. 9, a second lens element 46 of the 4f optics unit is arranged at a distance f2 from the first DOE 45. The distance f2, which is smaller than the distance f1, corresponds to the focal length of the second lens element 46. Arranged at a distance f2 on the other side of the second lens element 46 is a pupil-shaping mirror element or a mirror array 35 comprising a multiplicity of mirror elements which are movably suspended on a frame structure and whose orientation relative to the frame structure can be individually set. The near field of the laser light source 14 formed by the first DOE 45 is imaged onto the mirror array 35.

The mirror array 35 is arranged in a pupil plane 57 of the illumination system 16, and so radiation reflected off the mirror array 35 is distributed with uniform intensity over the first illumination field 22. The illumination setting, i.e., the angular distribution with which the radiation is incident on the first illumination field 22, can be varied by adjusting the mirror elements of the mirror array 35. The adjustment of the intensity distribution to the illumination setting carried out by the first DOE 45 is configured in such a way that mirror elements that contribute above average to the radiation incident on the first illumination field 22 are irradiated above average, and vice versa.

The illumination radiation is transmitted to a third optics assembly 37 using a second optics assembly 36, which also comprises a 4f optics unit and which serves for spatial filtering. The third optics assembly 37 comprises a first field DOE 48, used to generate the field, and a first field stop 49. A tube lens 38 and a polarization filter/polarization controller 39 are used to guide the illumination beam path 15 to a beam splitter 41, by means of which a first portion of the radiation is guided to the condenser optics unit 31 and a second portion of the radiation is guided to an energy monitor 40. The energy monitor 40 forms a reference for the amount of radiation that is guided to the first illumination field 22. In the subsequent image evaluation, the measured data recorded by the energy monitor 40 can be used to normalize the image data recorded by the image sensor 20 with respect to energy.

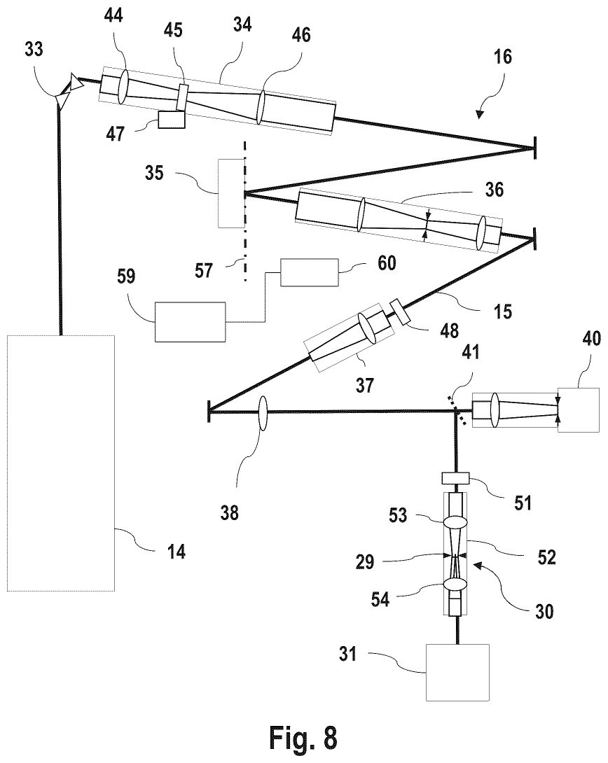

In the second measuring state, which is illustrated schematically in FIG. 8, a second field DOE 51 is arranged between the beam splitter 41 and the condenser optics unit 31. The field DOE 51 generates the field for the second (large) illumination field 23. A fourth optics assembly 52 is used to adapt the beam path to the condenser optics unit 31. The fourth optics assembly 52 comprises a further 4f optics unit. The second field stop 29, 30, which delimits the second illumination field 23 and masks the first illumination field 22, is arranged between the two lens elements of the 4f optics unit.

Some of the components arranged in the illumination beam path 15 in the first measuring state are removed for the second measuring state. These include the first field stop 49, which delimits the field in the first measuring state. These also include the polarization filter/polarization controller 39 and the beam attenuator 32.

The measuring device comprises actuators 60, which are indicated schematically in FIG. 8 and whose use allows components to be introduced into the illumination beam path 15 and removed from the illumination beam path 15. The measuring device comprises a control unit 59, which is designed to control the actuators 60 using control signals. In particular, the control unit 59 is designed to switch the measuring device between the first measuring state and the second measuring state. The control unit 59 may also be designed to control the exposure process. The exposure process may be longer in the second measuring state than in the first measuring state and, for example be 0.2 s in the first measuring state and be 2 s in the second measuring state.

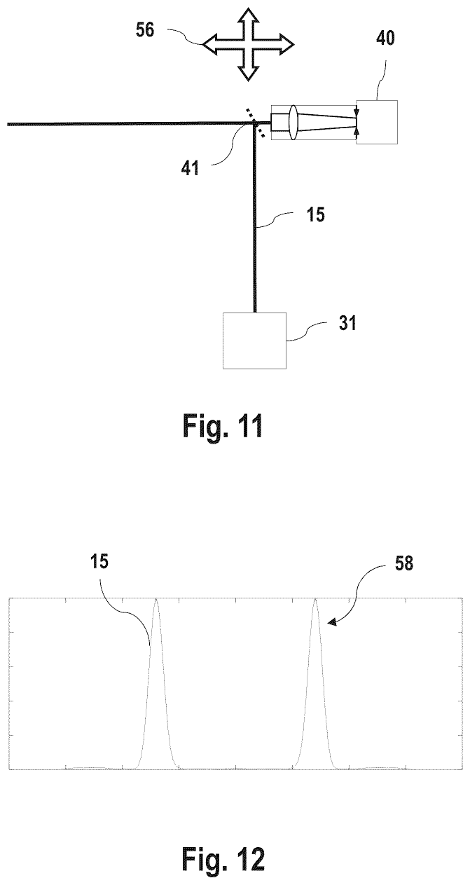

In an alternative embodiment of a measuring device according to the invention, shown in FIG. 11, the image sensor 20 is not exposed in a uniform exposure process; instead, the second illumination field 23 is scanned using a laser beam. To this end, the illumination system 16 is configured such that the radiation in the form of a concentrated laser beam is incident on the beam splitter 41. The alignment of the beam splitter 41 can be varied about two axes, and so the beam splitter 41 forms a scan optics unit that can be used to scan the second illumination field 23. An actuator 56 of the scan optics unit is indicated in FIG. 11.

What is claimed is:

1. A mask metrology measuring device, comprising a radiation source, an illumination system, an imaging system and an image sensor, with the illumination system being designed in a first measuring state to illuminate a first illumination field on a photomask with radiation emitted by the radiation source, and with the imaging system being designed to create an image representation on the image sensor from the first illumination field, with the measuring device being switchable between the first measuring state and a second measuring state, with a second illumination field on the photomask being illuminated in the second measuring state, with the first illumination field being arranged within the second illumination field, with the first illumination field not being illuminated in the second measuring state and with stray light generated in the second measuring state being recorded by the image sensor.

2. The measuring device of claim 1, wherein an inverted stop is arranged in the illumination beam path in the second measuring state and wherein the inverted stop masks the first illumination field.

3. The measuring device of claim 1, wherein the area of the second illumination field is smaller than the area of the photomask by at least a factor of 10⁵, preferably by at least a factor of 10⁷.

4. The measuring device of claim 1, wherein the area of the first illumination field is smaller than the area of the second illumination field by at least a factor of 10³, preferably by at least a factor of 10⁴.

5. The measuring device of claim 1, wherein a pupil-forming mirror element or a mirror array is arranged in a pupil plane of the illumination system and comprises a frame structure and a plurality of mirror elements movably mounted on the frame structure, and wherein the illumination system is configured such that the radiation incident on the mirror array has an intensity distribution (58) that is adapted to the illumination setting.

6. The measuring device of claim 5, wherein the illumination system comprises an interchange device arranged between the radiation source and the mirror array such that the radiation incident on the mirror array in a first state of the interchange device has a first intensity distribution that is adapted to a first illumination setting and that the radiation incident on the mirror array in a second state of the interchange device has a second intensity distribution that is adapted to a second illumination setting.

7. The measuring device of claim 5, wherein the illumination system is configured such that the beam path is reflected off a mirror array exactly once.

8. The measuring device of claim 1, comprising one or more actuators for moving optical components arranged in the illumination beam path, and having a control unit that is designed to control the actuators in order to switch the measuring device between the first measuring state and the second measuring state.

9. The measuring device of claim 1, wherein the exposure time of the image sensor is longer in the second measuring state than in the first measuring state.

10. The measuring device of claim 5, wherein a beam splitter is used to guide a portion of the radiation to an energy monitor and wherein the beam splitter is arranged in the illumination beam path between the mirror array and a condenser optics unit of the illumination system.

11. The measuring device of claim 1, wherein the illumination beam path is guided in the second measuring state to a scan optics unit and wherein the second illumination field is scanned with a laser beam.

12. The measuring device of claim 1, wherein the radiation is reflected off no more than five mirror surfaces, preferably off no more than four mirror surfaces, in the illumination system.

13. A method for examining a photomask, wherein a first illumination field on a photomask is illuminated in a first measurement run with radiation emitted by a radiation source, wherein an image representation is created on the image sensor from the first illumination field, wherein a second illumination field is illuminated on the photomask in a second measurement run, with the first illumination field being arranged within the second illumination field and with the first illumination field not being illuminated in the second measuring state, and wherein stray light generated in the second measuring state is recorded by the image sensor.

14. The method of claim 13, comprising arranging an inverted stop in the illumination beam path in the second measuring state and masking the first illumination field using the inverted stop.

15. The method of claim 13, wherein the area of the second illumination field is smaller than the area of the photomask by at least a factor of 10⁵.

16. The method of claim 13, wherein the area of the first illumination field is smaller than the area of the second illumination field by at least a factor of 10³.

17. The method of claim 13, comprising arranging a pupil-forming mirror element or a mirror array in a pupil plane of the illumination system, wherein the pupil-forming mirror element or the mirror array comprises a frame structure and a plurality of mirror elements movably mounted on the frame structure, and the method further comprises adapting the intensity distribution of the radiation incident on the mirror array to the illumination setting.

18. The method of claim 13, comprising arranging an interchange device between the radiation source and the mirror array such that the radiation incident on the mirror array in a first state of the interchange device has a first intensity distribution that is adapted to a first illumination setting and that the radiation incident on the mirror array in a second state of the interchange device has a second intensity distribution that is adapted to a second illumination setting.

19. The method of claim 13, comprising reflecting the beam path off a mirror array exactly once.

20. The method of claim 13, comprising moving optical components arranged in the illumination beam path using one or more actuators, and controlling, using a control unit, the actuators in order to switch the measuring device between the first measuring state and the second measuring state.
